(19) United States
(12) Patent Application Publication
(10) Pub. No.: US 2019/0221614 A1
(43) Pub. Date: Jul. 18, 2019

(54) DISPLAY PANEL AND METHOD OF MANUFACTURING THE SAME

(71) Applicant: Wuhan China Star Optoelectronics Semiconductor Display Technology Co., Ltd., Wuhan, Hubei (CN)

(72) Inventor: Songshan LI, Wuhan, Hubei (CN)

(21) Appl. No.: 15/578,308

(22) PCT Filed: Sep. 1, 2017
(86) PCT No.: PCT/CN2017/100264

§ 371 Date: Nov. 30, 2017

(30) Foreign Application Priority Data
Jul. 12, 2017 (CN) 201710566534.4

(51) Int. Cl. H01L 27/32; H01L 51/52; H01L 51/56

(52) U.S. Cl. CPC H01L 27/322; H01L 27/3244; H01L 51/5284; H01L 27/1225; H01L 51/56; H01L 2251/303; H01L 2227/323; H01L 51/5253

(57) ABSTRACT

The present disclosure provides a display panel includes a color filter film. The color filter film includes a light incident surface and a light exit surface opposite to the light incident surface, and a backplane having oxide thin film transistor is provided on the light incident surface of the color filter film. An anode, an organic light emitting layer and a cathode are deposited sequentially from the bottom to top on one surface of the oxide thin film transistor carried on the backplane. The present disclosure further provides a method of manufacturing a display panel. Compared with the prior art, the process flow of the present disclosure is simplified, the manufacturing cost is reduced, and the thickness of the display panel is further reduced due to the removal of polarizers.

### RELATED APPLICATIONS

The present application is a National Phase of International Application Number PCT/CN2017/100264, filed Sep. 1, 2017, and claims the priority of China Application No. 201710566534.4, filed Jul. 12, 2017.

### FIELD OF THE DISCLOSURE

The disclosure relates to a display panel technology, in particular to a display panel and a method of manufacturing the same.

### BACKGROUND

In a manufacturing process of a conventional OLED (organic light emitting diode) panel, the color filter (R, G, B color resist) is manufactured successively and an anode after completing Oxide TFT backplane (oxide thin film transistor back panel). And then the OLED organic light emitting material is evaporated to form an organic light emitting layer, and the cathode is further vapor-deposited and packaged. However, the display panel is normally displayed, and a polarizer is arranged on the surface of the oxide thin film transistor back panel facing away from the color filter film. It would be a complicated production process with high production cost. Also the display panel is thicker.

### SUMMARY

To overcome the deficiencies of the prior art, the present disclosure provides a display panel and a manufacturing method thereof, so as to simplify the process flow, reduce the manufacturing cost and reduce the thickness of the display panel.

The present disclosure provides a display panel. The display panel includes a color filter, which includes a light incident surface and a light exit surface opposite to the light incident surface, and a backplane having oxide TFTs on the light incident surface of the color filter film and an anode, an organic light emitting layer and a cathode deposited sequentially from the bottom to top on one surface of the backplane carrying with the oxide TFT.

Further, the color filter includes a black matrix and RGB color resists provided in a black matrix grid.

Further, an encapsulation layer is disposed on the cathode.

Further, material of the encapsulation layer is SiNx or SiOx.

The present disclosure also provides a method for manufacturing a display panel, which includes the following steps: Step S01: fabricating a color filter film, wherein the color filter film includes a light incident surface and a light exit surface opposite to the light exit surface; Step S02: fabricating a substrate on the light incident surface of the color filter, and fabricating an oxide TFT on the surface of the substrate facing away from the color filter; Step S03: fabricating an anode electrode on the surface of the substrate carrying the oxide thin film transistor and patterning the anode electrode to form an anode; Step S04: fabricating an organic light emitting layer on the anode; Step S05: forming a cathode electrode on the organic light emitting layer to form a cathode; Step S06: an encapsulation layer is formed on the cathode and encapsulated to obtain a display panel.

Further, the step S01 of manufacturing a color filter includes: Step S11: fabricating a black matrix; Step S12: an RGB color resist is fabricated in a black matrix. Further, Step S04 of forming the organic light emitting layer on the anode includes forming the organic light emitting layer on the anode by an evaporation process. Further, Step S05 of forming the cathode on the organic light emitting layer includes fabricating a cathode by an evaporation process. Further, the cathode is made of aluminum metal. Further, the material of the encapsulation layer is SiNx or SiOx.

Compared with the prior art, the present disclosure simplifies the process flow and reduces the manufacturing cost by fabricating the backplane on the light incident surface of the color filter and sequentially arranging the anode, the organic light emitting layer and the cathode on the backplane, Moreover, the thickness of the display panel is further reduced due to the removal of the polarizer.

### BRIEF DESCRIPTION OF THE DRAWINGS

FIG. 1 is a schematic diagram of a color e according to the present disclosure;

FIG. 2 is a schematic diagram of the backplane and the anode fabricated on a color filter according to the present disclosure;

FIG. 3 is a schematic structural view of the present disclosure.

### DETAILED DESCRIPTION OF PREFERRED EMBODIMENTS

The present disclosure will be further described in detail below with reference to the accompanying drawings and embodiments.

As shown in FIG. 3, a display panel according to the present disclosure, in particular OLED (organic light emitting diode display panel), comprises a color filter 2. The color filter 2 comprises a light incident surface and a light exit surface opposite to the light incident surface. A backplane 1 carrying oxide TFTs is arranged on the incident the light incident surface of the color filter 2. An anode 3, an organic light emitting layer 4 and a cathode 5 deposited sequentially from the bottom to top on one surface of the backplane carrying with the oxide TFT. An encapsulation layer 8 is disposed on the cathode to encapsulate the display panel. The present disclosure simplifies the process flow by directly fabricating the backplane 1 on the color filter film 2, thereby the manufacturing cost is saved and further the thickness of the display panel since no polarizer is needed to reduce.

As an embodiment of the present disclosure, the backplane carrying the oxide TFT adopts the prior art structure of the oxide array substrate. It will not be further described herein, but the present disclosure is not limited thereto. For example, the array substrate serves as the backplane of the present disclosure.

As an embodiment of the present disclosure, the color filter 2 comprises a black matrix 6 and RGB colors resist 7 in the grid barrier of the black matrix 6. The black matrix 6 replaces the function of the polarizer so that the display panel can display normally to further reduce manufacturing costs.

In the present disclosure, the cathode 5 is made of aluminum and has a thickness of 200 nm. The material of the encapsulating layer 8 is SiNx or SiOx. The anode 3 is made of a transparent ITO (Indium Tin Oxide) material.

In the present disclosure, the organic light emitting layer 4 includes a hole transport layer, a light emitting layer and an electron transport layer. It is noted that the organic light emitting layer 4 is a prior art and is not limited herein.

A method for fabricating a display panel of the present disclosure mainly improves a step of fabricating a device, and the manufacturing process involved is basically the same as the manufacturing process adopted in the prior art for preparing an OLED, and includes the following steps:

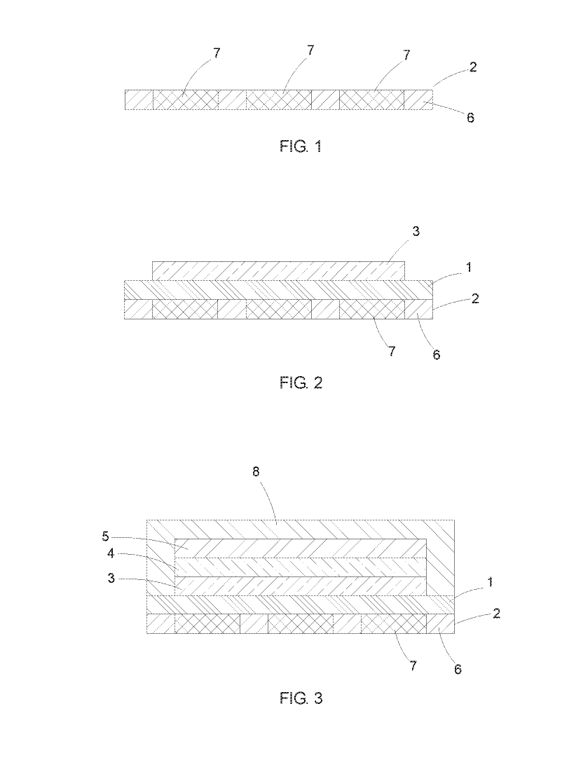

In step S01, shown in FIG. 1, in particular, the color filter 2, uses a photolithography process to produce a color filter 2, and the color filter 2 includes a light incident surface and a light exit surface opposite to the light incident surface.

Step S01 includes the following two steps:

In step S11, the production of a black matrix 6, using prior art made by a photolithography process;

In step S12, the RGB color filter 7 is made in the black matrix 6, and the RGB color filter manufacturing method adopts a lithographic process of the prior art.

In step S02, a substrate 1 is made on the light incident surface of the color filter substrate 1. Oxide TFTs are made on one side of the substrate facing away from the color filter 2. In the present disclosure, the substrate 1 is an oxide thin film transistor backplane;

In step S03, as shown in FIG. 2, an anode 3 is formed and patterned on the surface of the substrate 1 on which the oxide TFT is mounted. Specifically, transparent ITO (Indium Tin Oxide) is used as the anode formed on the surface of the substrate 1 on which the oxide thin film transistor is mounted. The anode 3 is formed by using the prior art photolithography process to pattern the ITO film.

Step S04, the production of the organic light emitting layer 4 is made on the anode 4. In particular, an organic thin film is made on the anode 4 by vapor deposition, to form the corresponding layer on the anode 3 by vapor deposition of multiple organic thin film layers. The organic light emitting layer 4 includes a hole transport layer, a light emitting layer and an electron transport layer. The vapor deposition process may be performed by vacuum deposition in a vacuum chamber, but it is not limited herein.

In step S05, a negative electrode is formed as a cathode on the organic light emitting layer. In particular, the cathode 5 is formed on the organic light emitting layer 4 through an evaporation process. The vapor deposition process can be performed in a vacuum chamber, but it is not limited herein. The material used for the cathode 5 is aluminum metal with a thickness of 200 nm.

In step S06, as shown in FIG. 3, an encapsulation layer 8 is fabricated on the cathode 5 to obtain a display panel. Specifically, the organic light emitting layer 4 and the cathode 5 are oxidized immediately after being exposed to water and air, so that the performance of the device is rapidly decreased. Thereby, the package needs to be encapsulated in a vacuum environment or by filling the cavity with an inert gas so as to avoid the influence of moisture and air on the device. The inert gas may be nitrogen. The packaging process can be performed in the prior art of the packaging process, but it is not limited herein. The encapsulation layer 8 is made of SiNx or SiOx.

In the present disclosure, the surface condition of the ITO film as an anode directly affects the injection of holes, the interface electron state between the organic thin film layer and the film forming property of the organic material. If the ITO surface is not clean, the free energy of the surface becomes smaller. It results in cohesion and filming uneven of the hole transport material when vapor deposition. Therefore, after the ITO film is manufactured, the surface of the ITO film can also be processed before the photolithography process. The treatment process is as follows: detergent cleaning, ethanol cleaning, acetone washing, and pure water washing. All steps are cleaned by the ultrasonic cleaner. Then, the infrared oven is used when drying. The cleaned ITO film needs to be surface-activated to increase the oxygen content of the ITO surface layer and improves the work function of the ITO surface.

Water, hydrogen peroxide, a mixed solution of aqueous ammonia hydrogen peroxide solution may be used to treat ITO surface oxidation, so that the tin content of the ITO surface reduces but excessive proportion of oxygen is increased. For increasing the work function of the ITO surface, the probability of hole injection can be increased. The brightness of the OLED device will increase an order of magnitude.

Before using the backplane having an ITO film, the surface treatment “UV ozone” or “plasma” needed to be executed. The main purpose is to remove residual organics on the ITO surface, cause ITO surface oxidation, increase in the work function of the ITO surface and a flat ITO surface degree. The work function of the untreated ITO surface is about 4.6 eV. The work of function of the ITO surface after ozone or plasma-treated surface is 5.0 eV or more, and the luminous efficiency and the working life will be improved. The ITO glass surface must be treated in a dry and vacuum environment. The treated substrate with the ITO film cannot be left in the air for too long or the ITO surface, or it will lose its activity.

Although the present disclosure is shown and described reference to particular embodiments, those skilled in the art will understand: without departing from the spirit and scope of the appended claims and their equivalents of the present disclosure, the case can be carried out in this form and various changes in detail.

What is claimed is:

1. A display panel, comprising: a color filter film, and the color filter film having a light incident surface and a light exit surface opposite to the light incident surface, a backplane having oxide thin film transistor on the light incident surface of the color filter film, and an anode, an organic light emitting layer and a cathode deposited sequentially from bottom to top on one surface of the oxide thin film transistor carried on the backplane.

2. The display panel according to claim 1, wherein the color filter comprises a black matrix and a RGB color resist provided in a black matrix grid.

3. The display panel according to claim 1, wherein an encapsulation layer is disposed on the cathode.

4. The display panel according to claim 2, wherein an encapsulation layer is disposed on the cathode.

5. The display panel according to claim 3, wherein material of the encapsulation layer is SiNx or SiOx.

6. The display panel according to claim 4, wherein material of the encapsulation layer is SiNx or SiOx.

7. A method of manufacturing a display panel, comprising:
Step S01: fabricating a color filter film, wherein the color filter film comprises a light incident surface and a light exit surface opposite to the light exit surface;
Step S02: fabricating a substrate on the light incident surface of the color filter, and fabricating an oxide thin film transistor on a surface of the substrate away from the color filter;
Step S03: fabricating an anode electrode on the surface of the substrate carrying with the oxide thin film transistor and patterning the anode electrode to form an anode;
Step S04: fabricating an organic light emitting layer on the anode;
Step S05: fabricating a cathode electrode on the organic light emitting layer to form a cathode;
Step S06: forming the display panel by sealing an encapsulation layer on the cathode.

8. The method of manufacturing the display panel according to claim 7, wherein Step S01 of fabricating a color filter comprises:
Step S11: fabricating a black matrix;
Step S12: fabricating a RGB color resist in the black matrix.

9. The method of manufacturing the display panel according to claim 7, wherein step S04 of fabricating an organic light emitting layer on the anode comprises forming the organic light emitting layer on the anode by an evaporation process.

10. The method of manufacturing the display panel according to claim 7, wherein step S05 of fabricating a cathode electrode on the organic light emitting layer comprises fabricating the cathode by an evaporation process.

11. The method of manufacturing the display panel according to claim 7, wherein the cathode is made of aluminum.

12. The method of manufacturing the display panel according to claim 10, wherein the cathode is made of aluminum.

13. The method of manufacturing the display panel according to claim 7, wherein material of the encapsulation layer is SiNx or SiOx.
